(19) United States
(12) Patent Application Publication
(10) Pub. No.: US 2011/0086490 A1
(43) Pub. Date: Apr. 14, 2011

(54) SINGLE-SIDE IMPLANTING PROCESS FOR CAPACITORS OF STACK DRAM

(75) Inventors: HSIAO-LEI WANG, Tainan City (TW); SHIN BIN HUANG, Hsinchu County (TW); CHING-NAN HSIAO, Kaohsiung County (TW); CHUNG-LIN HUANG, Taoyuan County (TW)

(73) Assignee: INOTERA MEMORIES, INC., TAOYUAN COUNTY (TW)

(21) Appl. No.: 12/720,977

(22) Filed: Mar. 10, 2010

(30) Foreign Application Priority Data
Oct. 14, 2009 (TW) 98134773

(51) Int. Cl. H01L 21/02; H01L 21/8242

(52) U.S. Cl. 438/396; 438/253; 438/514; 257/E21.011; 257/E21.648

(57) ABSTRACT

A single-side implanting process for capacitors of stack DRAM is disclosed. Firstly, form a stacked structure with a dielectric layer and an insulating nitride layer on a semi-conductor substrate and etch the stacked structure to form a plurality of trenches. Then, form conductive metal plates respectively on an upper surface of the stacked structure and bottoms of the trenches, form a continuous conductive nitride film, form a continuous oxide film, and form a photo resist layer for covering the trenches which are provided for isolation. Then, form a plurality of implanted oxide areas on a single-side surface, remove the photo resist layer, remove the plurality of implanted oxide areas, remove the conductive metal plates and the conductive nitride film uncovered by the oxide film, and remove the oxide film and the dielectric film.

### BACKGROUND OF THE INVENTION

1. Field of the Invention

The present invention relates to a single-side implanting process for capacitors of stack DRAM, and more particularly to a process for single-side implanting capacitors of stack DRAM.

2. Description of Related Art

DRAM (Dynamic Random Access Memory) is one kind of semiconductor memory, and each memory cell in DRAM is composed of a field effect transistor and a capacitor.

As shown in FIGS. 1-4, a conventional method for manufacturing a bottom capacitor electrode of a semiconductor memory is provided. Firstly, form a semi-conductor substrate 1a with a plurality of field effect transistors (not shown) and a plurality of conductive plugs 11a electrically with sources or bases of the field effect transistors. Secondly, form a stacked structure 2a on an upper surface of the semi-conductor substrate 1a, which includes a dielectric layer 21a and an insulating nitride layer 22a from down to up, and the dielectric layer 21a and the insulating nitride layer 22a have different etching rates for acid. As shown in FIG. 2, after the stacked structure 2a is formed, start to etch the partial dielectric layer 21a and insulating nitride layer 23a to form a plurality of through-holes 24a so that the conductive plugs 11a are exposed in the through-holes 24a. Then, dispose a conductive metal plate 25a in each through-hole 24a to contact the conductive plugs 11a, and form a plurality of bottom capacitor electrodes 26a in each through-hole 24a to press the upper surfaces of the conductive metal plates 25a. Then, as shown in FIG. 3, masking by photo resist 3a defined, remove the partial stacked structure 2a and the portions of the dielectric layer 21a, the insulating nitride layer 22a and the bottom capacitor electrodes 26a which aren't covered by the photo resist 3a via lattice etching. Finally, as shown in FIG. 4, etch and remove the dielectric layer 21a.

For improving data capacitor of memories, it must increase the density of memory cells, so process sizes must be reduced. With the decrease of the process sizes, it is more and more difficult to control the accuracy of the lattice etching process, so it is easy to cause the deviation of shapes and sizes of the top of capacitors, thereby the uniformity of capacitor structures cannot be ensured. Furthermore, the insulating nitride layer 22a support may be influenced by lattice patterning due to worse overlay control, which finally results in the collapse of capacitor structures.

Hence, the inventors of the present invention believe that the shortcomings described above are able to be improved and finally suggest the present invention which is of a reasonable design and is an effective improvement based on deep research and thought.

### SUMMARY OF THE INVENTION

A main object of the present invention is to provide a single-side implanting process for capacitors of stack DRAM which can improve uniformity of capacitor structures and provide a stable supporting ability for capacitor structures.

To achieve the above-mentioned object, a single-side implanting process for capacitors of stack DRAM in accordance with the present invention is provided. The process includes the steps of: forming a stacked structure on a semi-conductor substrate; etching the stacked structure at intervals to form a plurality of trenches; forming conductive metal plates respectively on an upper surface of the stacked structure and bottoms of the trenches, forming a conductive nitride film on upper surfaces of the conductive metal plates and inner sidewalls of the trenches, and forming an oxide film on a surface of the conductive nitride film; forming a photo resist layer filling in one part of the trenches; performing an inclined single-side implantation to form a plurality of implanted oxide areas in the oxide film on a single-side partial surface uncovered by the photo resist layer; removing the photo resist layer and etching and removing the plurality of implanted oxide areas; and etching and removing the conductive metal plates and the conductive nitride film in the areas uncovered by the oxide film.

The present invention further provides a single-side implanting process for capacitors of stack DRAM. The process includes the steps of: forming a stacked structure on a semi-conductor substrate; etching the stacked structure at intervals to form a plurality of trenches; forming conductive metal plates respectively on an upper surface of the stacked structure and bottoms of the trenches, forming a conductive nitride film on upper surfaces of the conductive metal plates and inner sidewalls of the trenches, and forming a polysilicon film on a surface of the conductive nitride film; performing an inclined single-side implantation to form a plurality of implanted polysilicon areas in the polysilicon film on a single-side partial surface; forming a photo resist layer filling in one part of the trenches; performing an inclined multi-side implantation to form implanted polysilicon areas in the polysilicon film on upper half portions and a horizontal surface around openings of the trenches uncovered by the photo resist layer; removing the photo resist layer, and forming a buffer layer to fill in the trenches and cover horizontal surfaces of tops of the trenches; grinding and removing the films and layers above a top surface of the insulating nitride layer; direct-etching the buffer layer in the trenches to be lower than the openings of the trenches; etching and removing the polysilicon film which is exposed and not implanted; and etching and removing the exposed conductive nitride film.

The present invention can avoid overlay deviation, so that each capacitor has the same structure and good uniformity. Furthermore, the complete insulating nitride layer can provide a good supporting ability for capacitor structures.

### BRIEF DESCRIPTION OF THE DRAWINGS

FIG. 1 is a first cross-sectional view of a process step of a conventional method;

FIG. 2 is a second cross-sectional view of a process step of a conventional method;

FIG. 3 is a third cross-sectional view of a process step of a conventional method;

FIG. 4 is a fourth cross-sectional view of a process step of a conventional method;

FIG. 5 is a first cross-sectional view of a process step of a first embodiment and a second embodiment of the present invention;

FIG. 6 is a second cross-sectional view of a process step of the first embodiment and the second embodiment of the present invention;

FIG. 7 is a third cross-sectional view of a process step of the first embodiment of the present invention;

FIG. 8 is a fourth cross-sectional view of a process step of the first embodiment of the present invention;

FIG. 9 is a fifth cross-sectional view of a process step of the first embodiment of the present invention;

FIG. 10 is a sixth cross-sectional view of a process step of the first embodiment of the present invention;

FIG. 11 is a seventh cross-sectional view of a process step of the first embodiment of the present invention;

FIG. 12 is an eighth cross-sectional view of a process step of the first embodiment of the present invention;

FIG. 13 is a third cross-sectional view of a process step of the second embodiment of the present invention;

FIG. 14 is a fourth cross-sectional view of a process step of the second embodiment of the present invention;

FIG. 15 is a fifth cross-sectional view of a process step of the second embodiment of the present invention;

FIG. 16 is a sixth cross-sectional view of a process step of the second embodiment of the present invention;

FIG. 17 is a seventh cross-sectional view of a process step of the second embodiment of the present invention;

FIG. 18 is an eighth cross-sectional view of a process step of the second embodiment of the present invention;

FIG. 19 is a ninth cross-sectional view of a process step of the second embodiment of the present invention;

FIG. 20 is a tenth cross-sectional view of a process step of the second embodiment of the present invention;

FIG. 21 is an eleventh cross-sectional view of a process step of the second embodiment of the present invention;

FIG. 22 is a twelfth cross-sectional view of a process step of the second embodiment of the present invention; and

FIG. 23 is a top view of a capacitor structure of the present invention.

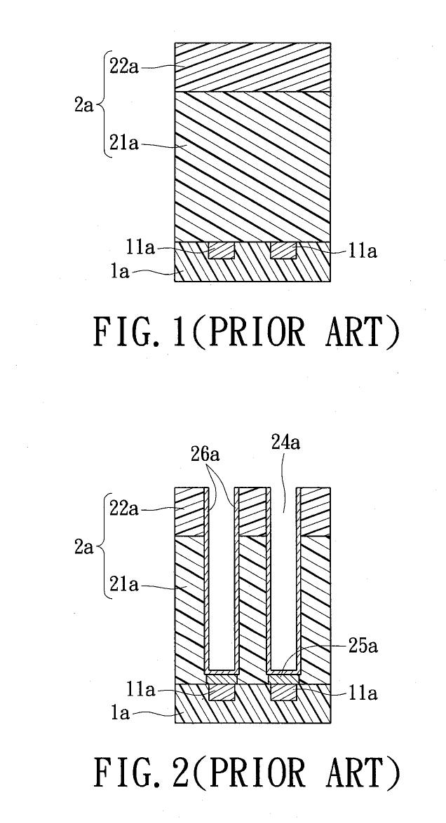

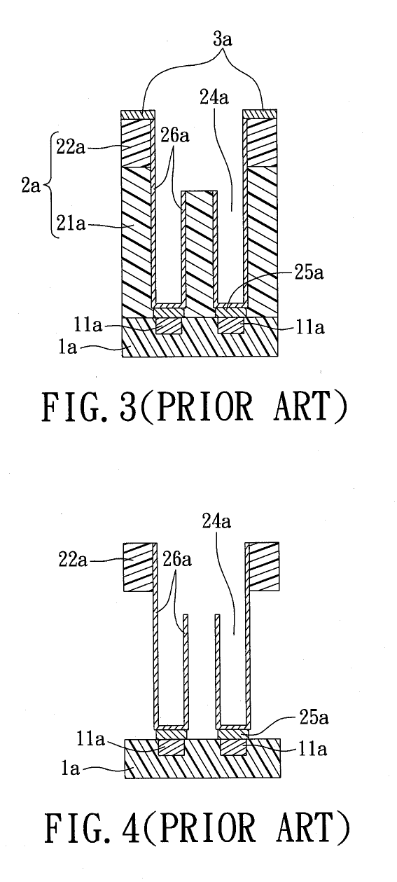

### DETAILED DESCRIPTION OF THE PREFERRED EMBODIMENTS

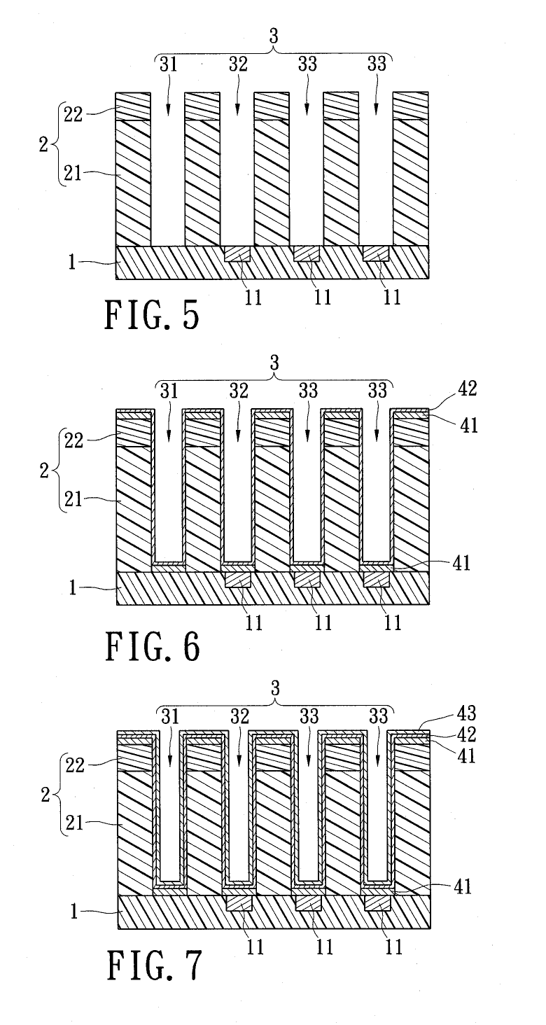

As shown in FIG. 5, at first, form a semi-conductor substrate 1 in which a plurality of conductive plugs 11 made from polysilicon materials and sources or bases (not shown) of field effect transistors electrically connected with the conductive plugs 11 are embedded. Then, form a stacked structure 2 on an upper surface of the semi-conductor substrate 1, wherein the stacked structure 2 includes a dielectric layer 21 and an insulating nitride layer 22, and the dielectric layer 21 is located on the semi-conductor substrate 1 and the insulating nitride layer 22 is located on the dielectric layer 21, and the material of the dielectric layer 21 is insulating oxide or polysilicon.

Secondly, etch the stacked structure 2 at intervals to form a plurality of trenches 3 which includes a moat 31, at least one dummy trench 32 and a plurality of capacitor trenches 33. All the trenches 3 extend from the top of the stacked structure 2 to the bottom thereof, and the dummy trench 32 and the capacitor trenches 33 correspond to the conductive plugs 11, so that the conductive plugs 11 are exposed on the bottoms of the dummy trench 32 and the capacitor trenches 33. The capacitor trenches 33 all are located behind the moat 31, the dummy trench 32 is located between the moat 31 and the capacitor trenches 33, and the moat 31 is used for isolating peripheral circuits (not shown) located in front of the moat 31 from the capacitor trenches 33 located behind the moat 31.

Then, as shown in FIG. 6, form conductive metal plates 41 respectively located on the upper surface of the insulating nitride layer 22 of the stacked structure 2 (uncover the openings of the trenches 3) and the bottoms of the trenches 3, wherein the conductive metal plates 41 located on the bottoms of the capacitor trenches 33 overlap the conductive plugs 11 to achieve the electrical connection. The material of the conductive metal plates 41 is titanium. A continuous conductive nitride film 42 is formed on the upper surfaces of the conductive metal plates 41 and the inner sidewalls of the trenches 3 so as to be electrically connected with the conductive metal plates 41. The material of the conductive nitride film 42 is titanium nitride. As shown in FIG. 7, a continuous oxide film 43 is formed on the surface of the conductive nitride film 42, and the material of the oxide film 43 is silicon oxide.

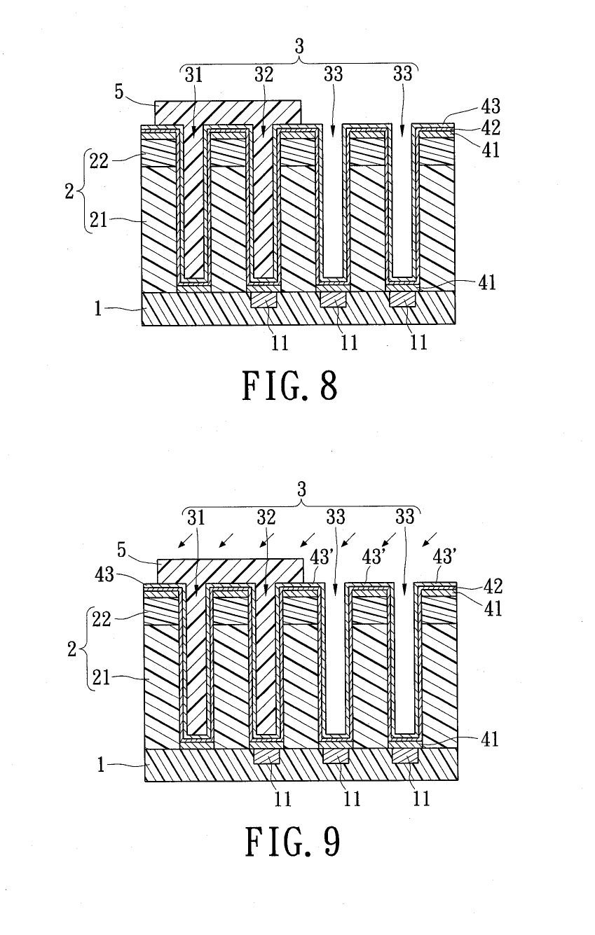

Then, as shown in FIG. 8, form a photo resist layer 5 to fill in the moat 31 and the dummy trench 32 and cover the top horizontal surface around the openings of the moat 31 and the dummy trench 32. As shown in FIG. 9, the single-side implanting process is performed in a single inclined direction (the implanting direction is the direction of inclined arrowheads). Ions are only implanted into the surface of the area which is uncovered by the photo resist layer 5 and faces to the single-side implanting direction, and aren't implanted into the area which is covered by the photo resist layer 5 and back against the single-side implanting direction and the lower half portions of the inner walls of the capacitor trenches 33, to form a plurality of implanted oxide areas 43′ in the portion of the oxide film 43 on the single-side partial surface uncovered by the photo resist layer 5, wherein the implanted ions herein may be phosphorus ions. When the oxide film 43 is etched, the implanted oxide areas 43′ have a much higher relative etching rate (etching selectivity) than that of the portion of the oxide film 43 in which the ions aren't implanted.

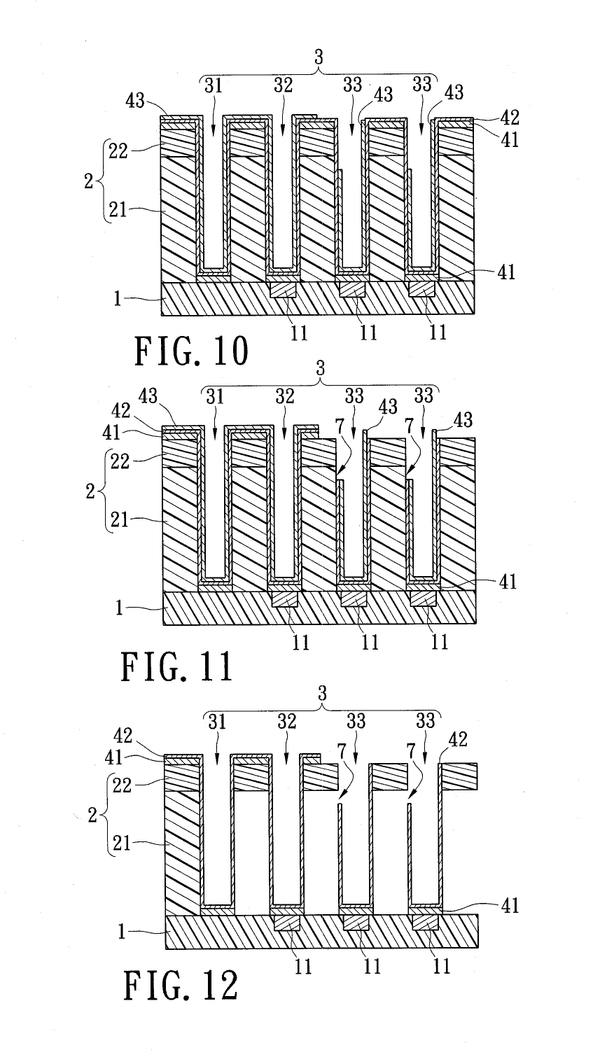

As shown in FIG. 10, remove the photo resist layer 5 and etch the oxide film 43. One kind of etching liquid may be Dilute Hydrofluoric Acid (DHF). Only the implanted oxide areas 43′ with a high etching rate are removed quickly, and the other portion of the oxide film 43 with a lower etching rate in which the ions aren't implanted is kept, the conductive nitride film 42 exposed partially.

Then, as shown in FIG. 11, etch the conductive metal plates 41 and the conductive nitride film 42. Etching liquid which is convenient for etching titanium and titanium nitride may be used. The conductive metal plates 41 and the conductive nitride film 42 in the area which is uncovered partially by the oxide film 43 are removed to form a plurality of gaps 7 which partially emerges from the dielectric layer 21. Finally, as shown in FIG. 12, etch and remove the oxide film 43, and etch and remove the whole dielectric layer 21 behind the moat 31 basing on the gaps 7. At this time, the conductive nitride film 42 is bottom capacitor electrodes, and the complete insulating nitride layer 22 support the bottom capacitor electrodes securely.

Please refer to FIGS. 5-6 and FIGS. 13-22 illustrating a second embodiment of the single-side implanting process for capacitors of stack DRAM according to the present invention. The former steps of the second embodiment of the present invention, as shown in FIG. 5 and FIG. 6, are the same with those of the first embodiment of the present invention.

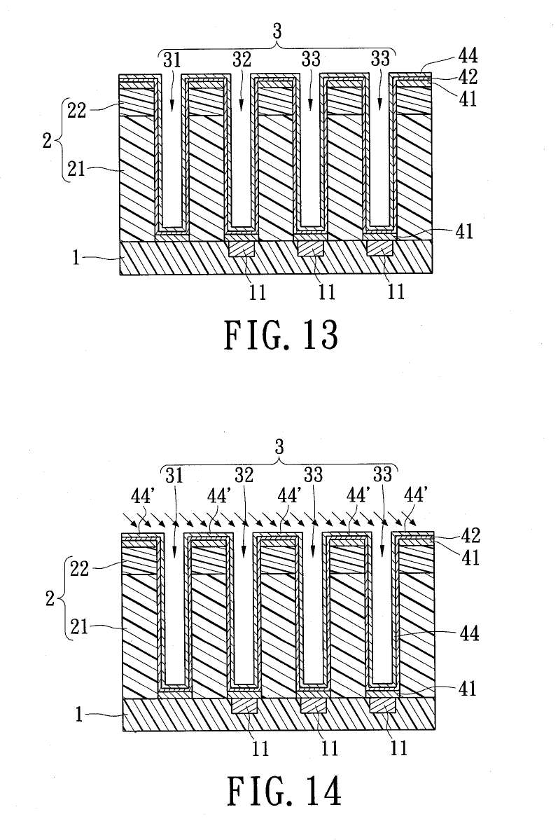

As shown in FIG. 6 and FIG. 13, after the continuous conductive nitride film 42 is formed on the upper surfaces of the conductive metal plates 41 and the inner sidewall of the trenches 3, a continuous polysilicon film 44 is formed on the surface of the continuous conductive nitride film 42. Then, as shown in FIG. 14, the single-side implanting process is performed in a single inclined direction (the implanting direction is the direction of inclined arrowheads). Ions are only implanted into the surface of the area facing to the single-side implanting direction, and aren't implanted into the area being back against the single-side implanting direction and the lower half portions of the inner walls of the trenches 3, wherein the implanted ions herein may be boron ions. When the polysilicon film 44 is etched, the implanted polysilicon areas 44′ have a much lower relative etching rate (etching selectivity) than that of the portion of the polysilicon film 44 in which the ions aren't implanted.

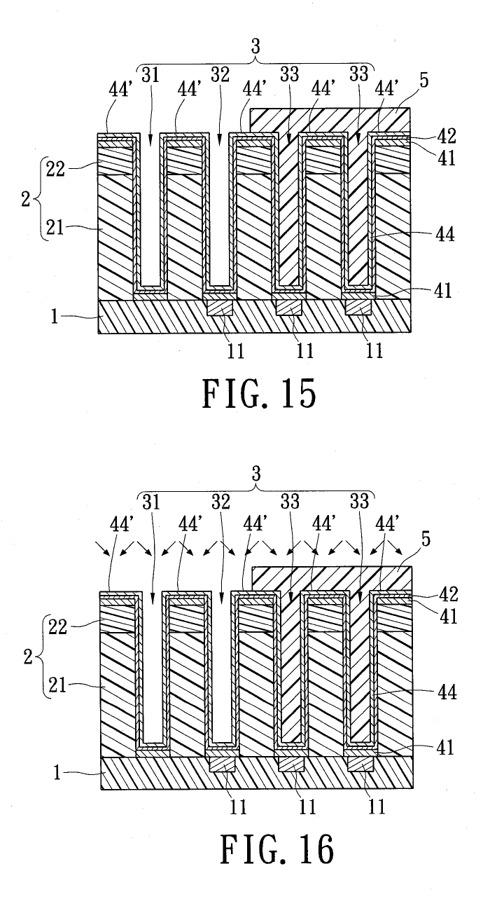

Then, as shown in FIG. 15, form a photo resist layer 5 to fill in the capacitor trenches 33 and cover the top horizontal surface around the openings of the capacitor trenches 33. As shown in FIG. 16, a multi-side implanting process is performed in inclined directions (the implanting directions are the directions of the inclined arrowheads). Ions are implanted into the surface of the area which isn't covered by the photo resist layer 5 and faces to the multi-side implanting directions to offset the portion of the area in which the ions aren't implanted during the single-side implanting process and form implanted polysilicon areas 44′ in the polysilicon film 44 on the upper half portions of the inner walls of the trenches 3 and the horizontal surface around the openings of the trenches 3 which are uncovered by the photo resist layer 5, wherein the implanted ions herein may be boron ions.

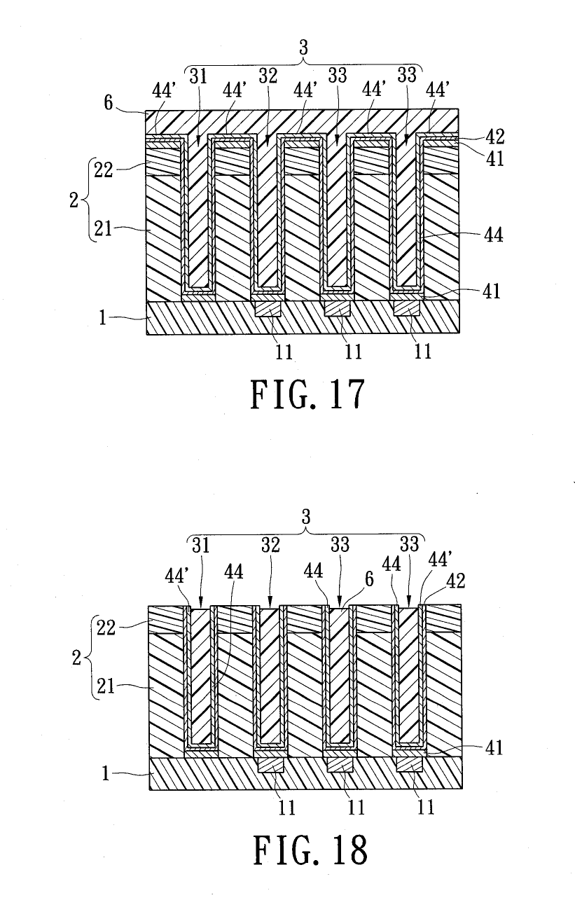

As shown in FIG. 17, form a buffer layer 6 after removing the photo resist layer 5. The buffer layer 6 fills in the trenches 3 and covers the horizontal surfaces of the tops of the trenches 3. Then as shown in FIG. 18, grind and remove the films and layers above the top surface of the insulating nitride layer 22 basing on chemical mechanical polishing. The buffer layer 6 is soft, so it can provide a buffer function during chemical mechanical polishing to avoid damaging the top surface directly, thereby obtaining a flat polished surface. The buffer layer 6 may be an anti-reflection coating (ARC).

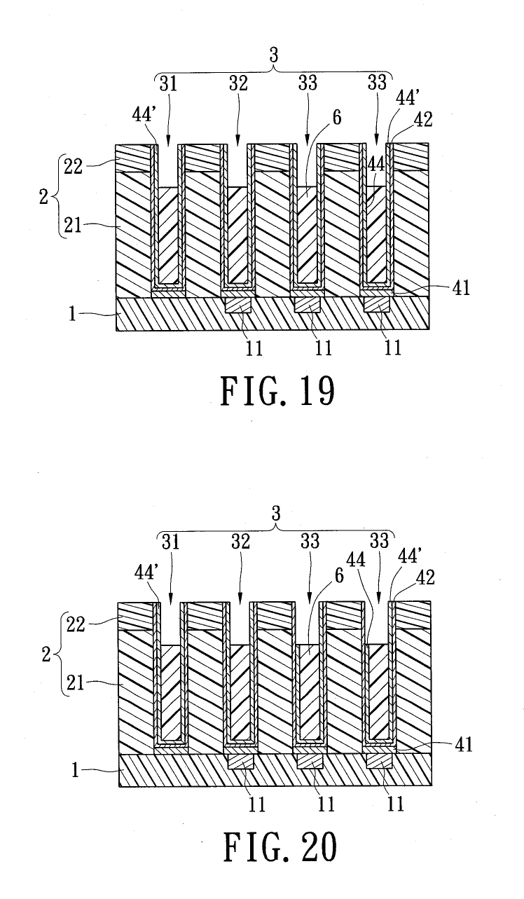

Then, as shown in FIG. 19, direct-etching the buffer layer 6 in the trenches 3 to a proper horizontal position below the openings of the trenches 3, which is lower than the bottom of the insulating nitride layer 22 and higher than the lowest horizontal position of the implanted polysilicon areas 44′. As shown in FIG. 20, etch the polysilicon film 44, wherein only the polysilicon film 44 with a high etching selectivity which is exposed and not implanted is removed quickly, and the other portion of the implanted polysilicon areas 44′ with a lower etching selectivity is kept, the conductive nitride film 42 exposed partially.

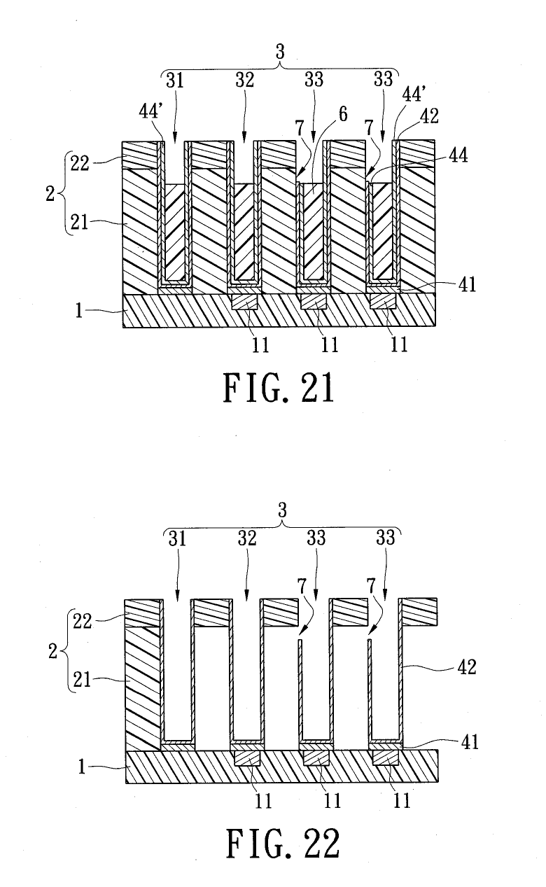

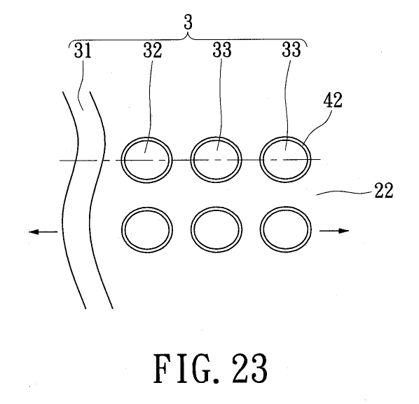

Then, as shown in FIG. 21, etch the conductive nitride film 42. Etching liquid which is convenient for etching titanium nitride may be used. The partially exposed conductive nitride film 42 is removed to form a plurality of gaps 7 which partially emerges from the dielectric layer 21. Finally, as shown in FIG. 22, etch and remove the buffer layer 6 and the polysilicon film 44, and etch and remove the whole dielectric layer 21 behind the moat 31 basing on the gaps 7. At this time, the conductive nitride film 42 is bottom capacitor electrodes, and the complete insulating nitride layer 22 support the bottom capacitor electrodes securely. The overlooked structure is as shown in FIG. 23, and the moat 31 is long-trench-shaped and the dummy trench 32 and the capacitor trenches 33 are slightly cylindrical trench-shaped.

Consequently, the single-side implanting process for capacitors of stack DRAM of the present invention has the advantages as follows:

1. The present invention can avoid overlay deviation, so that each capacitor has the same structure and good uniformity.

2. The complete insulating nitride layer 22 can provide a good supporting ability for capacitor structures to avoid collapse.

3. The first embodiment of the present invention can omit all the chemical mechanical polishing processes.

What are disclosed above are only the preferred embodiments of the present invention and it is therefore not intended that the present invention be limited to the particular embodiment disclosed. It will be understood by those skilled in the art that various equivalent changes may be made depending on the specification and the drawings of the present invention without departing from the scope of the present invention.

What is claimed is:

1. A single-side implanting process for capacitors of stack DRAM, comprising the steps of:
forming a stacked structure on a semi-conductor substrate;
etching the stacked structure at intervals to form a plurality of trenches;
forming conductive metal plates respectively on an upper surface of the stacked structure and bottoms of the trenches, forming a conductive nitride film on upper surfaces of the conductive metal plates and inner sidewalls of the trenches, and forming an oxide film on a surface of the conductive nitride film;
forming a photo resist layer filling in one part of the trenches;
performing an inclined single-side implantation to form a plurality of implanted oxide areas in the oxide film on a single-side partial surface uncovered by the photo resist layer;
removing the photo resist layer and etching and removing the plurality of implanted oxide areas; and
etching and removing the conductive metal plates and the conductive nitride film in the areas uncovered by the oxide film.

2. The single-side implanting process as claimed in claim 1, wherein the semi-conductor substrate has a plurality of conductive plugs and the stacked structure includes a dielectric layer and an insulating nitride layer, and the dielectric layer is located on the semi-conductor substrate and the insulating nitride layer is located on the dielectric layer.

3. The single-side implanting process as claimed in claim 2, wherein the material of the dielectric layer is insulating oxide or polysilicon.

4. The single-side implanting process as claimed in claim 2, wherein the plurality of trenches includes a moat, at least one dummy trench and a plurality of capacitor trenches, and the capacitor trenches all are located behind the moat and correspond to the conductive plugs and the dummy trench is located between the moat and the capacitor trenches.

5. The single-side implanting process as claimed in claim 4, wherein in the step of forming the photo resist layer, the photo resist layer fills in the moat and the dummy trench and covers a top horizontal surface around openings of the moat and the dummy trench.

6. The single-side implanting process as claimed in claim 4, wherein the moat is long-trench-shaped, and the dummy trench and the capacitor trenches are cylindrical trench-shaped.

7. The single-side implanting process as claimed in claim 5, further comprising etching and removing the oxide film and the dielectric layer behind the moat after etching and removing the conductive metal plates and the conductive nitride film in the areas uncovered by the oxide film.

8. The single-side implanting process as claimed in claim 1, wherein the material of the conductive metal plate is titanium, the material of the conductive nitride film is titanium nitride, and the material of the oxide film is silicon oxide.

9. The single-side implanting process as claimed in claim 1, wherein ions which are implanted in the implanted oxide areas are phosphorus ions.

10. The single-side implanting process as claimed in claim 1, wherein etching liquid for etching and removing the implanted oxide areas is hydrofluoric acid.

11. A single-side implanting process for capacitors of stack DRAM, comprising the steps of:
forming a stacked structure on a semi-conductor substrate;
etching the stacked structure at intervals to form a plurality of trenches;
forming conductive metal plates respectively on an upper surface of the stacked structure and bottoms of the trenches, forming a conductive nitride film on upper surfaces of the conductive metal plates and inner sidewalls of the trenches, and forming a polysilicon film on a surface of the conductive nitride film;
performing an inclined single-side implantation to form a plurality of implanted polysilicon areas in the polysilicon film on a single-side partial surface;
forming a photo resist layer filling in one part of the trenches;
performing an inclined multi-side implantation to form implanted polysilicon areas in the polysilicon film on upper half portions and a horizontal surface around openings of the trenches uncovered by the photo resist layer;
removing the photo resist layer, and forming a buffer layer to fill in the trenches and cover horizontal surfaces of tops of the trenches;
grinding and removing the films and layers above a top surface of the insulating nitride layer;
direct-etching the buffer layer in the trenches to be lower than the openings of the trenches;
etching and removing the polysilicon film which is exposed and not implanted; and
etching and removing the exposed conductive nitride film.

12. The single-side implanting process as claimed in claim 11, wherein the semi-conductor substrate has a plurality of conductive plugs and the stacked structure includes a dielectric layer and an insulating nitride layer, and the dielectric layer is located on the semi-conductor substrate and the insulating nitride layer is located on the dielectric layer.

13. The single-side implanting process as claimed in claim 12, wherein in the step of direct-etching the buffer layer in the trenches to be below the openings of the trenches, the buffer layer is direct-etched to be lower than a bottom of the insulating nitride layer and higher than the lowest horizontal position of the implanted polysilicon areas.

14. The single-side implanting process as claimed in claim 12, wherein the material of the dielectric layer is insulating oxide or polysilicon.

15. The single-side implanting process as claimed in claim 12, wherein the plurality of trenches includes a moat, at least one dummy trench and a plurality of capacitor trenches, and the capacitor trenches all are located behind the moat and correspond to the conductive plugs and the dummy trench is located between the moat and the capacitor trenches.

16. The single-side implanting process as claimed in claim 15, wherein in the step of forming the photo resist layer, the photo resist layer fills in the capacitor trenches.

17. The single-side implanting process as claimed in claim 15, wherein the moat is long-trench-shaped, and the dummy trench and the capacitor trenches are cylindrical trench-shaped.

18. The single-side implanting process as claimed in claim 16, further comprising etching and removing the buffer layer, the polysilicon film and the dielectric layer behind the moat after etching and removing the exposed conductive nitride film.

19. The single-side implanting process as claimed in claim 11, wherein the material of the conductive metal plate is titanium, the material of the conductive nitride film is titanium nitride, and ions which are implanted in the implanted polysilicon areas are boron ions.

20. The single-side implanting process as claimed in claim 11, wherein the buffer layer is an anti-reflection coating.
